(19) United States
(12) Patent Application Publication
(10) Pub. No.: US 2026/0114259 A1
(43) Pub. Date: Apr. 23, 2026

(54) SEMICONDUCTOR DEVICE INCLUDING AIR GAP PROTECTION STRUCTURE WITH UNEVEN THICKNESS AND MANUFACTURING METHOD THEREOF

(71) Applicant: NANYA TECHNOLOGY CORPORATION, NEW TAIPEI CITY (TW)

(72) Inventor: PING HSU, NEW TAIPEI CITY (TW)

(21) Appl. No.: 18/918,359

(22) Filed: Oct. 17, 2024

(51) Int. Cl. H01L 23/528; H01L 21/764; H01L 23/532

(52) U.S. Cl. CPC H10W 20/435; H10W 10/021; H10W 10/20; H10W 20/4403

(57) ABSTRACT

A semiconductor device and a method for manufacturing the same are provided. The semiconductor device includes a substrate, a bit line, an isolation spacer, a conductive layer, a landing pad, and an air gap protection structure. The substrate includes a plurality of liners disposed on side surfaces of a trench in the substrate. The bit line is disposed on the substrate. The isolation spacer is disposed on a sidewall of the bit line. The isolation spacer includes an air gap. The conductive layer is disposed over the substrate and next to the isolation spacer. The landing pad is disposed over the bit line. The air gap protection structure covers the landing pad and the air gap. The air gap protection structure includes an upper portion above a top surface of the landing pad and a lower portion below the upper portion.

### TECHNICAL FIELD

The present disclosure relates to a semiconductor device and a method for manufacturing the same, and more particularly, to a semiconductor device including an air gap protection structure with an uneven thickness and a method for manufacturing the same.

### DISCUSSION OF THE BACKGROUND

Integrated circuits (ICs) are becoming more powerful and smaller, with advances in materials and design leading to successive generations of smaller and more complex circuits.

Reducing overlay errors in lithography operations is becoming increasingly important. For example, when defining a pattern of a conductive wire to connect to a landing pad, a sufficiently large overlay error can cause the conductive wire to be misaligned with the landing pad, thus causing a material of the conductive wire to fill an air gap of an isolation spacer and negatively affect one or more electrical characteristics of a semiconductor device. Therefore, a new semiconductor device and method are required to mitigate such problems.

This Discussion of the Background section is provided for background information only. The statements in this Discussion of the Background are not an admission that the subject matter disclosed in this Discussion of the Background section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device. The semiconductor device comprises a substrate, a plurality of isolation structures disposed in the substrate, a bit line disposed on the substrate, an isolation spacer disposed on a sidewall of the bit line and comprising an air gap, a landing pad disposed over the bit line, and an air gap protection structure covering the landing pad and the air gap. The isolation structure comprises an isolation layer disposed in a trench in the substrate and a plurality of liners disposed on side surfaces of the trench.

Another aspect of the present disclosure provides a semiconductor device. The semiconductor device comprises a substrate, a bit line disposed on the substrate, an isolation spacer disposed on a sidewall of the bit line and comprising an air gap, a conductive layer disposed over the substrate and next to the isolation spacer, a landing pad disposed over the bit line, and an air gap protection structure covering the landing pad and the air gap. The conductive layer comprises a second portion and a first portion covering the second portion. The second portion comprises a semicircular cross-sectional profile or a semi-oval cross-sectional profile. The air gap protection structure comprises an upper portion above a top surface of the landing pad and a lower portion below the upper portion, and a ratio of a thickness of the lower portion to a thickness of the upper portion is greater than 0.6 and less than 0.8.

Another aspect of the present disclosure provides a method of manufacturing a semiconductor device. The method comprises providing a substrate having a first surface and a second surface opposite to the first surface, forming a trench in the first surface of the substrate, forming a plurality of liners disposed on side surfaces of the trench, forming an isolation layer filling the trench, and removing part of the substrate from the second surface to expose the isolation layer and the plurality of liners.

The embodiments of the present disclosure illustrate a semiconductor device including an air gap protection structure with an uneven thickness. The air gap protection structure includes a lower portion and an upper portion. A ratio of a thickness of the lower portion to a thickness of the upper portion is greater than 0.6 and less than 0.8, such that the air gap is protected from influence during subsequent processes. For example, an air gap of the present disclosure may be free of metal atoms or other contaminations due to the protection of an air gap protection structure. As a result, performance of the semiconductor device may be improved.

The foregoing has outlined rather broadly the features and technical advantages of the present disclosure in order that the detailed description of the disclosure that follows may be better understood. Additional features and advantages of the disclosure are described below, and form the subject of the claims of the disclosure. It should be appreciated by those skilled in the art that the conception and specific embodiments disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1A is a cross-sectional view of a semiconductor device in accordance with some embodiments of the present disclosure.

FIG. 1B is a partial enlarged view of a region R of the semiconductor device as shown in FIG. 1A in accordance with some embodiments of the present disclosure.

FIG. 2A illustrates one or more stages of a method of manufacturing a semiconductor device in accordance with some embodiments of the present disclosure.

FIG. 2B illustrates one or more stages of a method of manufacturing a semiconductor device in accordance with some embodiments of the present disclosure.

FIG. 2C illustrates one or more stages of a method of manufacturing a semiconductor device in accordance with some embodiments of the present disclosure.

FIG. 2D illustrates one or more stages of a method of manufacturing a semiconductor device in accordance with some embodiments of the present disclosure.

FIG. 2E illustrates one or more stages of a method of manufacturing a semiconductor device in accordance with some embodiments of the present disclosure.

FIG. 2F illustrates one or more stages of a method of manufacturing a semiconductor device in accordance with some embodiments of the present disclosure.

FIG. 2G illustrates one or more stages of a method of manufacturing a semiconductor device in accordance with some embodiments of the present disclosure.

FIG. 2H illustrates one or more stages of a method of manufacturing a semiconductor device in accordance with some embodiments of the present disclosure.

FIG. 2I illustrates one or more stages of a method of manufacturing a semiconductor device in accordance with some embodiments of the present disclosure.

FIG. 2J illustrates one or more stages of a method of manufacturing a semiconductor device in accordance with some embodiments of the present disclosure.

FIG. 2K illustrates one or more stages of a method of manufacturing a semiconductor device in accordance with some embodiments of the present disclosure.

FIG. 2L illustrates one or more stages of a method of manufacturing a semiconductor device in accordance with some embodiments of the present disclosure.

FIG. 3A and FIG. 3B are flowcharts illustrating a method of manufacturing a semiconductor device in accordance with some embodiments of the present disclosure.

FIG. 4A is a cross-sectional view of a semiconductor device in accordance with various embodiments of the present disclosure.

FIG. 5A illustrates one or more stages of a method of manufacturing a semiconductor device in accordance with various embodiments of the present disclosure.

FIG. 5B illustrates one or more stages of a method of manufacturing a semiconductor device in accordance with various embodiments of the present disclosure.

FIG. 5C illustrates one or more stages of a method of manufacturing a semiconductor device in accordance with various embodiments of the present disclosure.

FIG. 5D illustrates one or more stages of a method of manufacturing a semiconductor device in accordance with various embodiments of the present disclosure.

FIG. 5E illustrates one or more stages of a method of manufacturing a semiconductor device in accordance with various embodiments of the present disclosure.

FIG. 5F illustrates one or more stages of a method of manufacturing a semiconductor device in accordance with various embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features are not in direct contact. In addition, the present disclosure may repeat reference numerals and/or letters in the various examples. This repetition is for the purpose of simplicity and clarity and does not in itself dictate a relationship between the various embodiments and/or configurations discussed.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

The terminology used herein is for the purpose of describing particular example embodiments only and is not intended to be limiting to the present inventive concept. As used herein, the singular forms “a,” “an” and “the” are intended to include the plural forms as well, unless the context clearly indicates otherwise. It should be understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

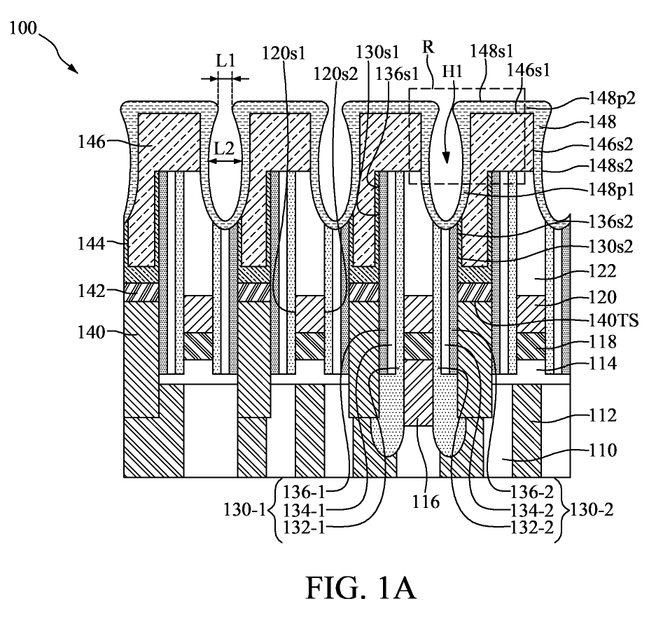

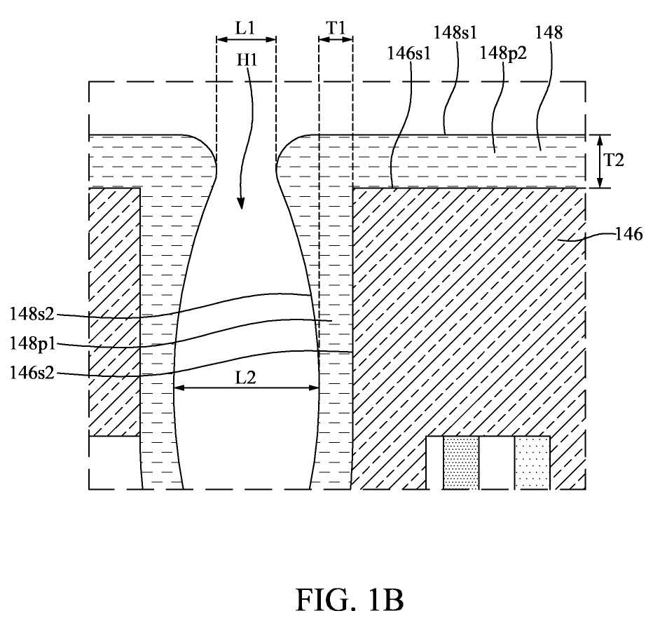

FIG. 1A is a cross-sectional view of a semiconductor device 100 in accordance with some embodiments of the present disclosure. In some embodiments, the semiconductor device 100 may include a cell region in which a memory device is formed. The memory device may include, for example, a dynamic random-access memory (DRAM) device, a one-time programming (OTP) device, a static random-access memory (SRAM) device, or other suitable devices. In some embodiments, a DRAM may include, for example, a transistor, a capacitor, and/or other components. During a read operation, a word line may be asserted, turning on a transistor. The enabled transistor allows a voltage across a capacitor to be read by a sense amplifier through a bit line. During a write operation, data to be written may be provided on a bit line when a word line is asserted.

In some embodiments, the semiconductor device 100 may include a peripheral region utilized to form a logic device (e.g., a system-on-a-chip (SoC), a central processing unit (CPU), a graphics processing unit (GPU), an application processor (AP), a microcontroller, etc.), a radio frequency (RF) device, a sensor device, a micro-electro-mechanical-system (MEMS) device, a signal processing device (e.g., a digital signal processing (DSP) device), a front-end device (e.g., an analog front-end (AFE) device) or other devices.

The semiconductor device 100 may include a substrate 110. The substrate 110 may be a semiconductor substrate, such as a bulk semiconductor, a semiconductor-on-insulator (SOI) substrate, or the like. The substrate 110 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; another suitable material; or a combination thereof. In some embodiments, the alloy semiconductor substrate may be a SiGe alloy with a gradient SiGe feature in which the Si and Ge composition changes from one ratio at one location to another ratio at another location of the gradient SiGe feature. In some embodiments, the SiGe alloy is formed over a silicon substrate. In some embodiments, a SiGe alloy can be mechanically strained by another material in contact with the SiGe alloy. In some embodiments, the substrate 110 may have a multilayered structure, or the substrate 110 may include a multilayered compound semiconductor structure.

In some embodiments, the substrate 110 may include a plurality of active areas. The active area may function as, for example, a channel for electrical connection.

In some embodiments, the semiconductor device 100 may include a plurality of isolation structures 112. In some embodiments, the active areas may be separated by the isolation structures 112. In some embodiments, the isolation structures 112 may be embedded in the substrate 110. In some embodiments, the isolation structures 112 may include, for example, silicon oxide (SiO₂), silicon nitride (Si₃N₄), silicon oxynitride (N₂OSi₂), silicon nitride oxide (N₂OSi₂), or another suitable material.

In some embodiments, the semiconductor device 100 may include a dielectric layer 114. The dielectric layer 114 may be disposed on the substrate 110. In some embodiments, the dielectric layer 114 may cover a portion of the isolation structures 112. In some embodiments, the dielectric layer 114 may include, for example, silicon oxide (SiO₂), silicon nitride (Si₃N₄), silicon oxynitride (N₂OSi₂), silicon nitride oxide (N₂OSi₂), a high-k material, or a combination thereof. Examples of the high-k material include a dielectric material that has a dielectric constant greater than that of silicon dioxide (SiO₂), or a dielectric material that has a dielectric constant greater than about 3.9. In some embodiments, the dielectric layer 114 may include at least one metallic element, such as hafnium oxide (HfO₂), silicon-doped hafnium oxide (HSO), lanthanum oxide (La₂O₃), lanthanum aluminum oxide (LaAlO₃), zirconium orthosilicate (ZrSiO₄), aluminum oxide (Al₂O₃) or a combination thereof.

In some embodiments, the semiconductor device 100 may include a bit line contact 116. In some embodiments, the bit line contact 116 may be disposed on the active area of the substrate 110. The bit line contact 116 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), an alloy thereof, a combination thereof, or a metallic material with suitable resistance and gap-fill capability.

In some embodiments, the semiconductor device 100 may include a plurality of bit line stacks 118. In some embodiments, the bit line stack 118 may include a multilayered structure. In some embodiments, a portion of the bit line stacks 118 may be disposed on the bit line contact 116. In some embodiments, a portion of the bit line stacks 118 may be in contact with the bit line contact 116. In some embodiments, a portion of the bit line stacks 118 may be electrically connected to the bit line contact 116. In some embodiments, a portion of the bit line stacks 118 may be disposed on the dielectric layer 114. In some embodiments, a portion of the bit line stacks 118 may be in contact with the dielectric layer 114. The bit line stack 118 may include titanium (Ti), tantalum (Ta), titanium nitride (TiN), tantalum nitride (TaN), manganese nitride (MnN), or a combination thereof.

In some embodiments, the semiconductor device 100 may include a plurality of bit lines 120. In some embodiments, each of the bit lines 120 may be disposed on the bit line stack 118. In some embodiments, a portion of the bit lines 120 may be disposed over the bit line contact 116. In some embodiments, a portion of the bit lines 120 may be electrically connected to the bit line contact 116. In some embodiments, a portion of the bit lines 120 may be disposed on the dielectric layer 114. The bit line 120 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), an alloy thereof, or a combination thereof.

In some embodiments, the semiconductor device 100 may include a plurality of dielectric layers 122. In some embodiments, each of the dielectric layers 122 may be disposed on the bit line 120. In some embodiments, the dielectric layer 122 may include, for example, silicon oxide, silicon nitride, silicon oxynitride, silicon nitride oxide, a high-k material, or a combination thereof.

In some embodiments, the semiconductor device 100 may include a plurality of isolation spacers 130-1 and 130-2. The isolation spacer 130-1 may be disposed on a sidewall 120s1 of the bit line 120. The isolation spacer 130-2 may be disposed on a sidewall 120s2 of the bit line 120. Although FIG. 1A shows the isolation spacers 130-1 and 130-2 being separated in a cross-sectional view, it should be noted that from a top view perspective, the isolation spacers 130-1 and 130-2 may be a part of an integral (or monolithic) structure, with the integral structure having a circular profile, an elliptical profile, or the like.

In some embodiments, the isolation spacer 130-1 may have a dielectric layer 132-1, an air gap 134-1, and a dielectric layer 136-1. In some embodiments, the isolation spacer 130-2 may have a dielectric layer 132-2, an air gap 134-2, and a dielectric layer 136-2. In some embodiments, the dielectric layers 132-1 and 132-2 may be formed on sidewalls of the bit line contact 116, the bit line stack 118, the bit line 120, and the dielectric layer 122. For example, the dielectric layer 132-1 may be formed on the sidewall 120s1 of the bit line 120, and the dielectric layer 132-2 may be formed on the sidewall 120s2 of the bit line 120. In some embodiments, the dielectric layer 132-1 may be in contact with the sidewall 120s1 of the bit line 120. In some embodiments, the dielectric layer 132-2 may be in contact with the sidewall 120s2 of the bit line 120. In some embodiments, a portion of the dielectric layer 132-1 may be embedded in the substrate 110. In some embodiments, a portion of the dielectric layer 132-2 may be embedded in the substrate 110.

In some embodiments, the air gap 134-1 may be separated from the bit line 120 by the dielectric layer 132-1. In some embodiments, the air gap 134-2 may be separated from the bit line 120 by the dielectric layer 132-2. In some embodiments, the air gap 134-1 may be disposed between the dielectric layers 132-1 and 136-1. In some embodiments, the air gap 134-2 may be disposed between the dielectric layers 132-2 and 136-2. In some embodiments, a length of the air gap 134-2 may be less than a length of the air gap 134-1. Although FIG. 1 shows that the air gap 134-1 is separate from or distinct from the air gap 134-2, it should be noted that, in some embodiments, the air gap 134-1 may be connected to the air gap 134-2.

In some embodiments, the dielectric layer 136-1 may be disposed on the dielectric layer 132-1. In some embodiments, the dielectric layer 136-2 may be disposed on the dielectric layer 132-2. In some embodiments, each of the dielectric layers 132-1, 132-2, 136-1 and 136-2 may include, for example, silicon oxide, silicon nitride, silicon oxynitride, silicon nitride oxide, a high-k material, or a combination thereof. Although FIG. 1A shows that the dielectric layer 132-1 is separated from the dielectric layer 136-1, in some embodiments, the dielectric layer 132-1 may be connected to the dielectric layer 136-1.

In some embodiments, the semiconductor device 100 may include a capacitor contact 140. In some embodiments, the capacitor contact 140 may be formed between two bit lines 120. In some embodiments, the capacitor contact 140 may be formed between the isolation spacers 130-1 and 130-2. In some embodiments, the capacitor contact 140 may be formed between the dielectric layers 136-1 and 136-2. In some embodiments, the capacitor contact 140 may be formed between a sidewall 130s1 of the isolation spacer 130-1 and a sidewall 130s2 of the isolation spacer 130-2. The capacitor contact 140 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), an alloy thereof, a combination thereof, or another metallic material.

In some embodiments, the semiconductor device 100 may include a stacking conductive structure 142. The stacking conductive structure 142 may include a multilayered structure. In some embodiments, the stacking conductive structure 142 may be formed on a top surface of the capacitor contact 140. In some embodiments, the stacking conductive structure 142 may include a metal silicide, such as cobalt silicide (CoSi), or another suitable material.

In some embodiments, the semiconductor device 100 may include a liner 144. In some embodiments, the liner 144 may be formed on a top surface of the stacking conductive structure 142. In some embodiments, the liner 144 may be formed on the sidewall 130s1 of the isolation spacer 130-1. In some embodiments, the liner 144 may be formed on a sidewall of the dielectric layer 136-1. In some embodiments, the liner 144 may be formed on the sidewall 130s2 of the isolation spacer 130-2. In some embodiments, the liner 144 may be formed on a sidewall of the dielectric layer 136-2. In some embodiments, the liner 144 may include a metal nitride, such as titanium nitride (TiN), or another suitable material.

In some embodiments, the semiconductor device 100 may include a plurality of landing pads 146. The landing pad 146 may be configured to electrically connect to a capacitor structure (not shown). In some embodiments, the landing pad 146 may be formed on the liner 144. In some embodiments, the landing pad 146 may be formed between two bit lines 120. In some embodiments, the landing pad 146 may be formed between the isolation spacers 130-1 and 130-2. In some embodiments, the landing pad 146 may cover a top surface of the isolation spacer 130-1. In some embodiments, the landing pad 146 may cover a top surface of the dielectric layer 132-1. In some embodiments, the landing pad 146 may cover a top surface of the dielectric layer 136-1. In some embodiments, the air gap 134-1 may be covered by the landing pad 146. In some embodiments, the air gap 134-2 may be free from being vertically overlapped by the landing pad 146. In some embodiments, a portion of the landing pad 146 may be surrounded by the liner 144. In some embodiments, the landing pad 146 may cover a top surface of the dielectric layer 122. In some embodiments, the landing pad 146 may include an upper portion over the dielectric layer 122 and a lower portion between adjacent dielectric layers 122. In some embodiments, the landing pad 146 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), an alloy thereof, or a combination thereof. The landing pad 146 may have a surface 146s1 and a surface 146s2. The surface 146s1 (or a top surface) may face away from the substrate 110. The surface 146s2 (or a lateral surface) may be continuous with a lateral surface of the dielectric layer 122.

In some embodiments, the landing pad 146, the dielectric layer 122, and the isolation spacer 130-2 may define a hole H1 (or an opening). The hole H1 may have an aspect ratio equal to or greater than 2, such as 2, 2.3, 2.5, 2.8, 3, or greater. The aspect ratio may be defined as a ratio of a width (or an aperture) of the hole H1 (e.g., a distance between adjacent landing pads) to a depth of the hole H1 (e.g., a distance between the surface 146s1 and a top of the isolation spacer 130-2).

In some embodiments, the semiconductor device 100 may include an air gap protection structure 148. In some embodiments, a portion of the air gap protection structure 148 may be disposed within the hole H1. In some embodiments, the air gap protection structure 148 may cover the landing pads 146. In some embodiments, the air gap protection structure 148 may cover the isolation spacer 130-2. In some embodiments, the air gap 134-2 may be covered by the air gap protection structure 148. In some embodiments, the air gap protection structure 148 may be separated from the isolation spacer 130-1 by the landing pad 146. The air gap protection structure 148 may have a surface 148s1 and a surface 148s2. The surface 148s1 (or a top surface) may face away from the substrate 110. The surface 148s2 (or a lateral surface) may cover the surface 146s2. The air gap protection structure 148 may be configured to protect the air gap 134-2 to ensure a desired parasitic capacitance. In some embodiments, the air gap protection structure 148 may have an uneven thickness. In some embodiments, the air gap protection structure 148 may include silicon nitride and other impurities. In some embodiments, the air gap protection structure 148 may include atoms, molecules, or ions of silicon, carbon, nitrogen, and hydrogen. In some embodiments, the air gap protection structure 148 may consist of carbon with an atomic ratio equal to or greater than 4.8%, such as 4.8%, 4.9%, 5%, or more. In some embodiments, the air gap protection structure 148 may consist of silicon with an atomic ratio between about 48% and about 50%. In some embodiments, the air gap protection structure 148 may consist of nitrogen with an atomic ratio between about 46% and about 49%. In some embodiments, an amount of silicon in the air gap protection structure 148 may be greater than an amount of nitrogen in the air gap protection structure 148.

Referring to FIG. 1B, the air gap protection structure 148 may have a lower portion 148p1 with a thickness T1 between the surfaces 146s2 and 148s2 and an upper portion 148p2 with a thickness T2 between the surfaces 146s1 and 148s1. The lower portion 148p1 may be disposed within the hole H1. The upper portion 148p2 may be located over the lower portion 148p1 and over the surface 146s1. In some embodiments, the thickness T1 may be less than the thickness T2. In some embodiments, a ratio of the thickness T1 to the thickness T2 may be between about 0.6 and about 0.8. In some embodiments, a ratio of the thickness T1 to the thickness T2 may be greater than 0.6, such as 0.61, 0.62, 0.63, 0.64, 0.65, 0.66, 0.67, 0.68, 0.69, 0.7, 0.72, 0.74, 0.76, 0.78, or 0.8.

As mentioned above, the hole defined by the landing pad and the isolation structure has a relatively great aspect ratio (e.g., an aspect ratio greater than 2) and a narrower aperture at the top so that a dielectric material is prevented from easily filling the hole. As a result, the lower portion of the air gap protection structure may have an insufficient thickness to effectively protect the air gap, leading to a high parasitic capacitance. When a ratio of the thickness T1 of the lower portion 148p1 of the air gap protection structure 148 to the thickness T2 of the upper portion 148p2 of the air gap protection structure 148 is greater than 0.6, preferably equal to 0.66 or more, the air gap 134-2 may be protected from influence during subsequent processes. For example, in a comparative embodiment, metal atoms or other contaminations may diffuse into the air gap 134-2 in subsequent processes because the air gap 134-2 is not effectively protected. In contrast, in the current embodiment, the air gap 134-2 may be free of metal atoms or other contaminations due to the protection by the air gap protection structure 148, the lower portion 148p1 of which has a relatively large thickness.

The hole H1 defined by the air gap protection structure 148 may have a width L1 (or aperture) at the top (e.g., at the surface 148s1) of the air gap protection structure 148 and a width L2 (or aperture) at the middle or bottom of the air gap protection structure 148. In some embodiments, the width L1 may be less than the width L2.

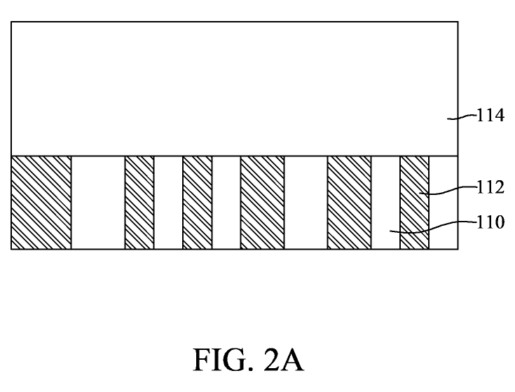

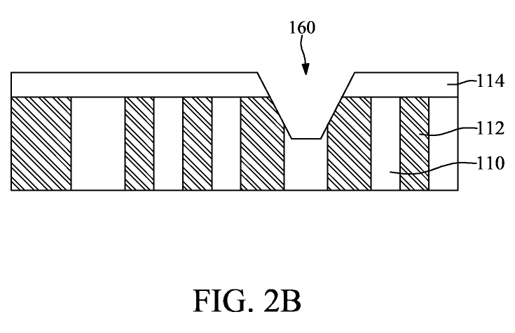

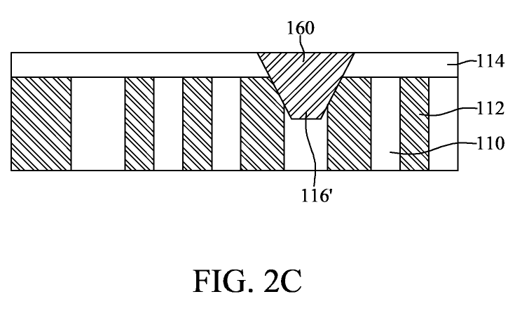

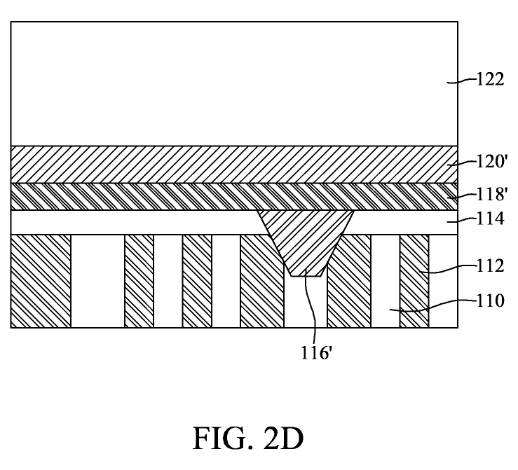

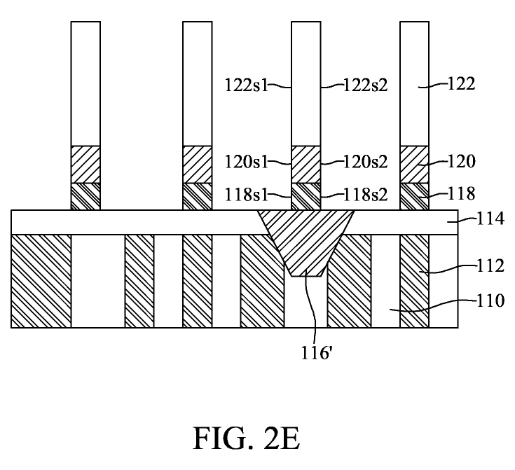

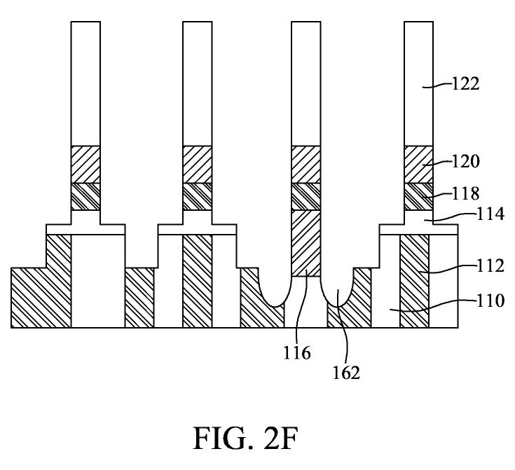

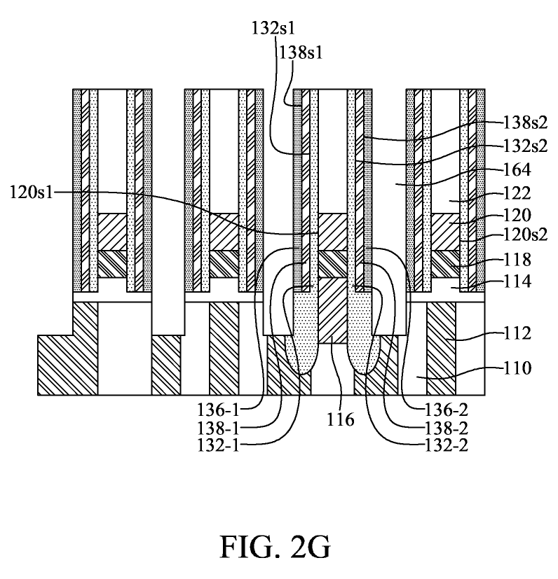

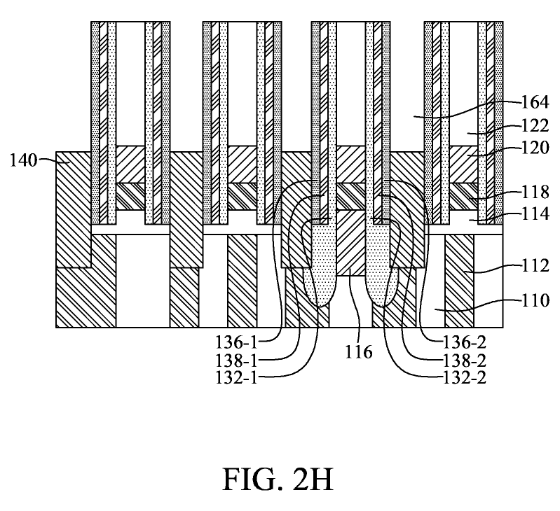

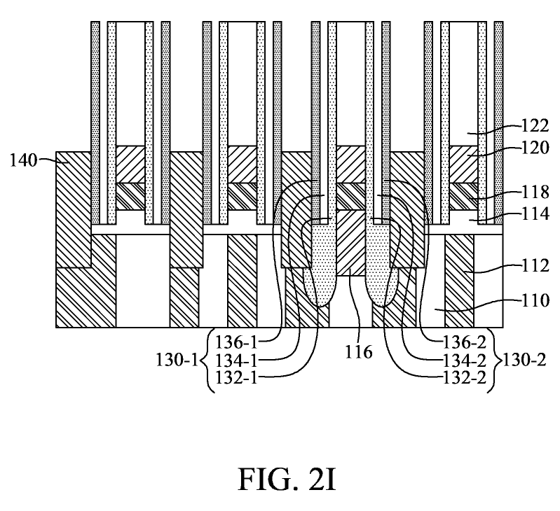

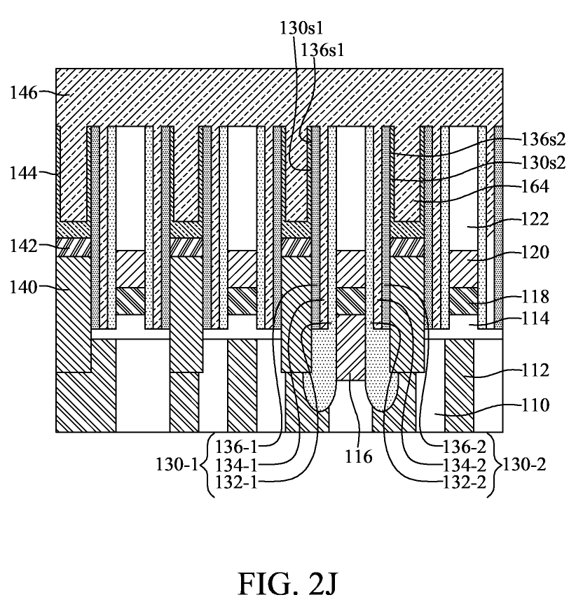

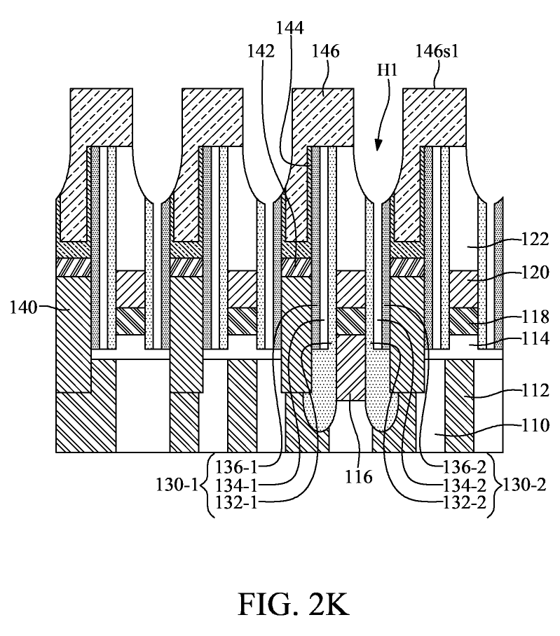

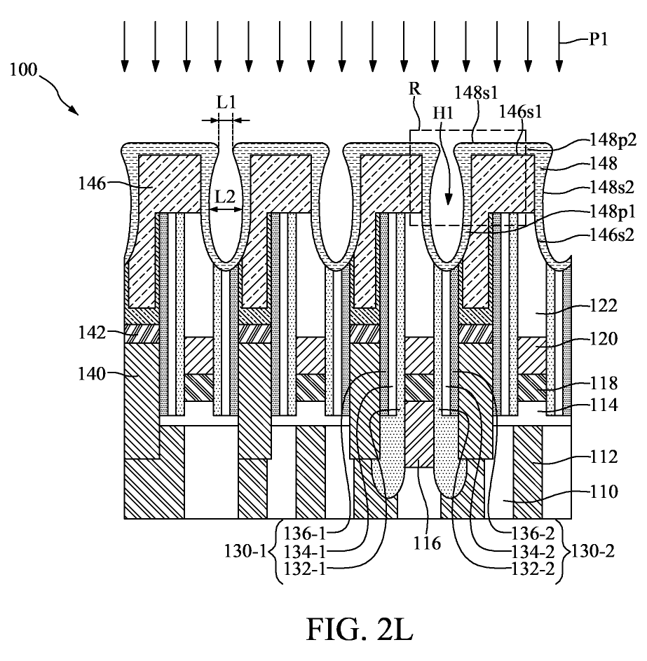

FIGS. 2A to 2L illustrate stages of a method of manufacturing a semiconductor device 100 in accordance with some embodiments of the present disclosure.

Referring to FIG. 2A, a substrate 110 is provided. In some embodiments, the substrate 110 may include a plurality of active areas separated by a plurality of isolation structures 112. A dielectric layer 114 may be formed on the substrate 110. In some embodiments, the substrate 110 may include the active areas and the isolation structures 112. In some embodiments, the dielectric layer 114 may be formed by chemical vapor deposition (CVD), atomic layer deposition (ALD), physical vapor deposition (PVD), low-pressure chemical vapor deposition (LPCVD), flowable chemical vapor deposition (FCVD), or other suitable processes.

Referring to FIG. 2B, a trench 160 may be formed. In some embodiments, the trench 160 may be recessed into a top surface of the substrate 110. In some embodiments, the trench 160 may be recessed into a top surface of the dielectric layer 114. In some embodiments, the trench 160 may be defined by the dielectric layer 114, the substrate 110, and the isolation structures 112. In some embodiments, an etching process may be performed to form the trench 160. The etching process may include dry etching, wet etching, or a combination thereof.

Referring to FIG. 2C, a conductive layer 116' may be formed. In some embodiments, the conductive layer 116' may fill the trench 160. In some embodiments, the conductive layer 116' may be surrounded by the dielectric layer 114. In some embodiments, the conductive layer 116' may be surrounded by the substrate 110. In some embodiments, the conductive layer 116' may be formed by CVD, ALD, PVD, FCVD, LPCVD, or other suitable processes. In addition, a chemical polishing process may be performed to planarize top surfaces of the conductive material 116' and the dielectric layer 114.

Referring to FIG. 2D, a barrier layer 118', a metallization layer 120', and a dielectric layer 122 may be sequentially formed. The barrier layer 118' may be formed by CVD, ALD, PVD, FCVD, LPCVD, or other suitable processes. The metallization layer 120' may be formed on the barrier layer 118'. The metallization layer 120' may be formed by CVD, ALD, PVD, FCVD, LPCVD, or other suitable processes. The dielectric layer 122 may be formed on the metallization layer 120'. The dielectric layer 122 may be formed by CVD, ALD, PVD, FCVD, LPCVD, or other suitable processes.

In some embodiments, the barrier layer 118' may cover the substrate 110. In some embodiments, the barrier layer 118' may cover the dielectric layer 114.

In some embodiments, the metallization layer 120' may be configured to form bit lines 120. In some embodiments, the metallization layer 120' may cover the barrier layer 118'.

In some embodiments, the dielectric layer 122 may cover the metallization layer 120'.

Referring to FIG. 2E, a portion of the metallization layer 120' may be removed, thereby forming a plurality of bit lines 120. In some embodiments, a portion of the barrier layer 118' may be removed, thereby forming a plurality of bit line stacks 118. In some embodiments, a portion of the dielectric layer 122 may be removed. An etching process may be performed to remove the portions of the metallization layer 120', the barrier layer 118', and the dielectric layer 122. The etching process may include dry etching, wet etching, or other suitable processes.

In some embodiments, a sidewall 120s1 of the bit line 120 may be exposed. A sidewall 120s2 of the bit line 120 may be exposed. It should be noted that, from a top view perspective, each of the dielectric layer 122, the bit line 120, and the bit line stack 118 may have a circular profile, an elliptical profile, or the like, and sidewalls of the dielectric layer 122, the bit line 120, and the bit line stack 118 may appear as a lateral edge in a cross-sectional view.

In some embodiments, a portion of the conductive layer 116' may be exposed by the bit line stack 118. In some embodiments, the portion of the conductive layer 116' may be exposed by the bit line 120. In some embodiments, the portion of the conductive layer 116' may be exposed by the dielectric layer 122.

In some embodiments, a portion of the bit lines 120 may be disposed over the conductive layer 116'. In some embodiments, a portion of the bit line stacks 118 may be disposed over the conductive layer 116'. In some embodiments, a portion of the bit lines 120 may be disposed over the isolation structures 112. In some embodiments, a portion of the bit line stacks 118 may be disposed over the isolation structures 112.

Referring to FIG. 2F, a portion of the conductive layer 116' is removed, thereby forming a bit line contact 116 within a trench 162. In some embodiments, the portion of the conductive layer 116' exposed by the bit line 120 may be removed. In some embodiments, the portion of the conductive layer 116' exposed by the bit line stack 118 may be removed. In some embodiments, the portion of the conductive layer 116' exposed by the dielectric layer 122 may be removed. In some embodiments, the bit line contact 116 may be tapered along a direction from the bit line 120 toward the substrate 110.

Referring to FIG. 2G, a plurality of dielectric layers 132-1, 132-2, 138-1, 138-2, 136-1 and 136-2 may be formed. In some embodiments, the dielectric layers 132-1 and 132-2 may be formed on sidewalls of the bit line contact 116, the bit line stack 118, the bit line 120, and the dielectric layer 122. For example, the dielectric layer 132-1 may be formed on the sidewall 120s1 of the bit line 120, and the dielectric layer 132-2 may be formed on the sidewall 120s2 of the bit line 120. In some embodiments, the dielectric layer 132-1 may be in contact with the sidewall 120s1 of the bit line 120. In some embodiments, the dielectric layer 132-2 may be in contact with the sidewall 120s2 of the bit line 120. It should be noted that the dielectric layer 132-1 and the dielectric layer 132-2 may be a part of an integral (or monolithic) structure, and from a top view perspective, the integral structure may have a circular profile, an elliptical profile, or the like.

In some embodiments, the dielectric layer 138-1 may be disposed on a sidewall 132s1 of the dielectric layer 132-1. In some embodiments, the dielectric layer 138-2 may be disposed on a sidewall 132s2 of the dielectric layer 132-2. It should be noted that the dielectric layers 138-1 and 138-2 may be a part of an integral (or monolithic) structure, and from a top view perspective, the integral structure may have a circular profile, an elliptical profile, or the like from a top view.

In some embodiments, the dielectric layer 136-1 may be disposed on a sidewall 138s1 of the dielectric layer 138-1. In some embodiments, the dielectric layer 136-2 may be disposed on a sidewall 138s2 of the dielectric layer 138-2. In some embodiments, the dielectric layer 136-1 may be separated from the dielectric layer 132-1 by the dielectric layer 138-1. In some embodiments, the dielectric layer 136-2 may be separated from the dielectric layer 132-2 by the dielectric layer 138-2. It should be noted that the dielectric layers 136-1 and 136-2 may be a part of an integral (or monolithic) structure, and from a top view perspective, the integral structure may have a circular profile, an elliptical profile, or the like.

In some embodiments, the dielectric layer 138-1 may be formed of a material different from materials of the dielectric layers 132-1 and 136-1. In some embodiments, the dielectric layer 132-1 may be formed of a material same as a material of the dielectric layer 136-1. In some embodiments, the dielectric layer 138-2 may be formed of a material different from materials of the dielectric layers 132-2 and 136-2. In some embodiments, the dielectric layer 132-2 may be formed of a material same as a material of the dielectric layer 136-2. A trench 164 may be defined between the dielectric layers 136-1 and 136-2. Profiles of the dielectric layers 132-1, 132-2, 138-1, 138-2, 136-1, and 136-2 may be modified by suitable etching processes, and the present disclosure is not intended to be limiting.

Referring to FIG. 2H, a capacitor contact 140 may be formed. The capacitor contact 140 may be formed in the trench 164. The capacitor contact 140 may be formed by, for example, CVD, ALD, PVD, FCVD, LPCVD, or other suitable processes. In some embodiments, the capacitor contact 140 may be formed between two bit lines 120. In some embodiments, the capacitor contact 140 may be formed between the dielectric layers 136-1 and 136-2.

Referring to FIG. 2I, the dielectric layer 138-1 may be removed, thereby forming an air gap 134-1. The dielectric layer 138-2 may be removed, thereby forming an air gap 134-2. As a result, a plurality of isolation spacers 130-1 and 130-2 are produced. In some embodiments, the air gap 134-1 may be separated from the bit line 120 by the dielectric layer 132-1. In some embodiments, the air gap 134-2 may be separated from the bit line 120 by the dielectric layer 132-2. The dielectric layer 138-1 and dielectric layer 138-2 may be removed by an etching process, such as dry etching, wet etching, or a combination thereof.

Referring to FIG. 2J, a stacking conductive structure 142, a liner 144, and a landing pad 146 may be formed. The stacking conductive structure 142 may be formed in the trench 164. In some embodiments, the stacking conductive structure 142 may be formed on a top surface of the capacitor contact 140. In some embodiments, the stacking conductive structure 142 may be formed between the dielectric layers 136-1 and 136-2. The stacking conductive structure 142, the liner 144, and the landing pad 146 may be formed by CVD, ALD, PVD, FCVD, LPCVD, or other suitable process.

In some embodiments, the liner 144 may be formed over a top surface of the stacking conductive structure 142. In some embodiments, the liner 144 may be formed on a sidewall 130s1 of the isolation spacer 130-1. In some embodiments, the liner 144 may be formed on a sidewall 136s1 of the dielectric layer 136-1. In some embodiments, the liner 144 may be formed on a sidewall 130s2 of the isolation spacer 130-2. In some embodiments, the liner 144 may be formed on a sidewall 136s2 of the dielectric layer 136-2.

In some embodiments, the landing pad 146 may be formed on the liner 144. In some embodiments, the landing pad 146 may be formed between two bit lines 120. In some embodiments, the landing pad 146 may be formed between the isolation spacers 130-1 and 130-2. In some embodiments, the landing pad 146 may cover a top surface of the isolation spacer 130-1. In some embodiments, the landing pad 146 may cover a top surface of the dielectric layer 132-1. In some embodiments, the landing pad 146 may cover a top surface of the dielectric layer 136-1. In some embodiments, the air gap 134-1 may be covered by the landing pad 146. In some embodiments, the landing pad 146 may cover a top surface of the dielectric layer 132-2. In some embodiments, the landing pad 146 may cover a top surface of the dielectric layer 136-2. In some embodiments, the air gap 134-2 may be covered by the landing pad 146. In some embodiments, the landing pad 146 may cover a top surface of the dielectric layer 122. In some embodiments, the landing pad 146 may be formed in the trench 164 defined by the isolation spacers 130-1 and 130-2.

Referring to FIG. 2K, a portion of the landing pad 146 may be removed or patterned. Holes H1 may be defined by the landing pads 146, the dielectric layer 122, and the isolation spacer 130-2. The portions of the landing pads 146 may be removed by an etching process. In some embodiments, the holes H1 may have an aspect ratio greater than 2.

Referring to FIG. 2L, a deposition process P1 may be performed to form an air gap protection structure 148 within the holes H1, which thereby produces a semiconductor device 100. The air gap protection structure 148 may be formed by ALD, CVD, PVD, or other suitable processes. The air gap protection structure 148 may have a lower portion 148p1 and an upper portion 148p2. In some embodiments, a ratio of a thickness of the lower portion 148p1 to a thickness of the upper portion 148p2 may be greater than 0.6, preferably equal to or greater than 0.66.

In some embodiments, the hole H1 may have a smaller width or aperture (e.g., L1) at a top (e.g., at a surface 148s1) of the air gap protection structure 148 and a larger width or aperture (e.g., L2) at a middle or bottom of the air gap protection structure 148.

In some embodiments, the air gap protection structure 148 may include silicon nitride and other impurities, such as carbon and/or hydrogen. In some embodiments, a temperature of the deposition process P1 may range from about 530 °C to about 570 °C, such as 530 °C, 540 °C, 550 °C, 560 °C, or 570 °C.

In some embodiments, a pressure of the deposition process P1 may be equal to or less than 3 torr, such as 3 torr, 2.5 torr, 2 torr, 1.5 torr, or 1 torr, or less.

In some embodiments, the deposition process P1 may include using gas, including reactive gas(s) and non-reactive gas(s), of silane (SiH₄), ammonia (NH₃), tetramethylsilane (TMS), nitrogen (N₂), or a combination thereof. In some embodiments, the deposition process P1 is free of helium (He). More specifically, during the step of depositing the air gap protection structure 148, He is not used. However, during stages before or after the deposition of the air gap protection structure 148, such as heating, cooling, purging, or other steps, He may be used.

In some embodiments, during the deposition process P1, a flow rate of the SiH₄ may be equal to or greater than 200 sccm, such as 200 sccm, 220 sccm, 240 sccm, 260 sccm, 280 sccm, 300 sccm, 320 sccm, or more.

In some embodiments, during the deposition process P1, a flow rate of the NH₃ may be equal to or greater than 600 sccm, such as 600 sccm, 1,500 sccm, 2,200 sccm, 2,700 sccm, 3,200 sccm, 4,000 sccm, or more.

In some embodiments, during the deposition process P1, a flow rate of the TMS may be equal to or greater than 45 sccm, such as 45 sccm, 48 sccm, 50 sccm, 55 sccm, or more.

In some embodiments, during the deposition process P1, a flow rate of the N₂ may be equal to or less than 10,000 sccm, such as 10,000 sccm, 7,000 sccm, 4,000 sccm, 1,000 sccm, or less.

In some embodiments, a deposition rate of the air gap protection structure 148 may be equal to or less than 15 Å/sec, such as 12 Å/sec, 10 Å/sec, 8 Å/sec, 5 Å/sec, or less.

Due to the process conditions mentioned above, a ratio of the thickness T1 to the thickness T2 of the air gap protection structure 148 may be greater than 0.6, thereby protecting the air gap 134-2 during subsequent processes.

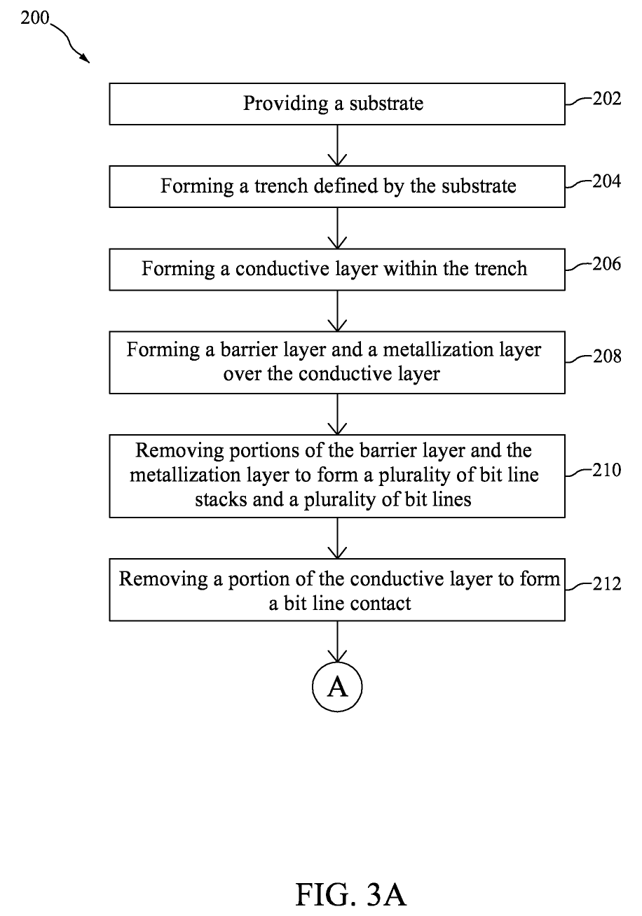

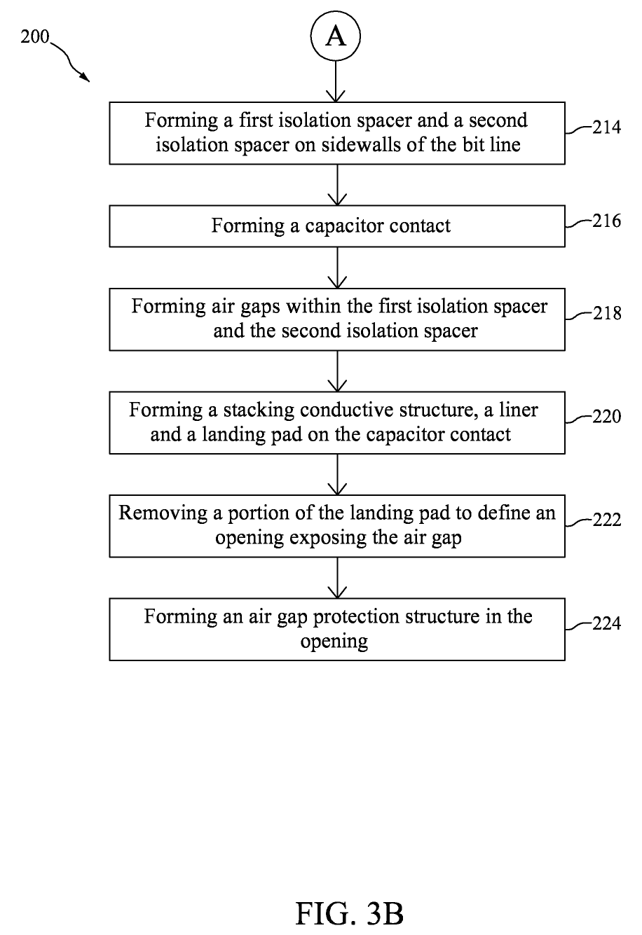

FIGS. 3A and 3B are flowcharts illustrating a method 200 of manufacturing a semiconductor device in accordance with some embodiments of the present disclosure.

Referring to FIG. 3A, the method 200 begins with operation 202, wherein a substrate is provided. For example, as shown in FIG. 2A, the substrate 110 may be provided. The substrate 110 may include a plurality of active areas separated by isolation structures 112. In some embodiments, a first dielectric layer 114 may be formed on the substrate 110. In some embodiments, the substrate 110 may include the active areas and the isolation structures 112. In some embodiments, a plurality of word lines may be formed in the substrate 110.

The method 200 continues with operation 204, wherein a trench may be formed. For example, as shown in FIG. 2B, the trench 160 may be formed in the substrate 110. The trench 160 is defined by the substrate 110. The trench 160 may be formed by an etching process. In some embodiments, the trench 160 may be recessed into the substrate 110. In some embodiments, the trench 160 may be recessed into the first dielectric layer 114. In some embodiments, the trench 160 may be defined by the first dielectric layer 114, the substrate 110, and the isolation structures 112.

The method 200 continues with operation 206, wherein a conductive layer is formed in the trench 160. For example, as shown in FIG. 2C, the conductive layer 116’ may be formed in the trench 160. The conductive layer 116’ may fill the trench 160. In some embodiments, the conductive layer 116’ may be surrounded by the first dielectric layer 114.

The method 200 continues with operation 208, wherein a barrier layer, a metallization layer, and a second dielectric layer may be formed. The barrier layer may cover the substrate 110. The metallization layer may be formed on the barrier layer. The second dielectric layer may be formed on the metallization layer. For example, as shown in FIG. 2D, the barrier layer 118’, the metallization layer 120’, and the dielectric layer 122 may be formed. The barrier layer 118’ may cover the substrate 110. The metallization layer 120’ may be formed on the barrier layer 118’. The dielectric layer 122 may be formed on the metallization layer 120’.

The method 200 continues with operation 210, wherein a portion of the barrier layer and a portion of the metallization layer are removed to form a plurality of bit line stacks and a plurality of bit lines. For example, as shown in FIG. 2E, the portion of the barrier layer 118’ may be removed to form the plurality of bit line stacks 118, and the portion of the metallization layer 120’ may be removed to form the plurality of bit lines 120. In some embodiments, a portion of the dielectric layer 122 may be removed. An etching process may be performed to remove the portions of the metallization layer 120’, the barrier layer 118’, and the dielectric layer 122.

In some embodiments, sidewalls 120s1, 120s2 of the bit line 120 may be exposed. In some embodiments, sidewalls 118s1, 118s2 of the bit line stack 118 may be exposed. In some embodiments, sidewalls 122s1, 122s2 of the dielectric layer may be exposed.

In some embodiments, a portion of the conductive layer 116’ may be exposed by the bit line stack 118. In some embodiments, the portion of the conductive layer 116’ may be exposed by the bit line 120. In some embodiments, the portion of the conductive layer 116’ may be exposed by the dielectric layer 122.

In some embodiments, a portion of the bit line 120 may be disposed over the conductive layer 116’. In some embodiments, a portion of the bit line stack 118 may be disposed over the conductive layer 116’. In some embodiments, a portion of the bit line 120 may be disposed over the isolation structure 112. In some embodiments, a portion of the bit line stack 118 may be disposed over the isolation structure 112.

The method 200 continues with operation 212, wherein a portion of the conductive layer 116' is removed to form a bit line contact in a trench. For example, as shown in FIG. 2F, the portion of the conductive layer 116’ exposed by the bit line 120 may be removed to form the bit line contact 116 in the trench 162. In some embodiments, the portion of the conductive layer 116’ exposed by the dielectric layer 122 may be removed to form the bit line contact 116 in the trench 162. The bit line contact 116 may be tapered from the bit line 120 toward the substrate 110.

Referring to FIG. 3B, the method 200 continues with operation 214, wherein a first isolation spacer and a second isolation spacer may be formed on sidewalls of the bit line. For example, as shown in FIG. 2G, an isolation spacer comprising dielectric layers 132-1, 136-1 and 138-1 may be formed on the first sidewall 120s1 of the bit line 120, and another isolation spacer comprising dielectric layers 132-2, 136-2 and 138-2 may be formed on the second sidewall 120s2 of the bit line 120. Each of the first isolation spacer (i.e., the dielectric layers 132-1, 138-1 and 136-1) and the second isolation spacer (i.e., the dielectric layers 132-2, 138-2 and 136-2) may have a multilayered structure. In some embodiments, the first isolation spacer and the second isolation spacer may be made of silicon nitride/silicon oxide/silicon nitride.

The method 200 continues with operation 216, wherein a capacitor contact may be formed. For example, as shown in FIG. 2H, the capacitor contact 140 may be formed. In some embodiments, an etching process may be performed to remove a portion of the substrate 110 and the dielectric layer 114 to form a trench 164, and the capacitor contact 140 may be formed in the trench 164. In some embodiments, the capacitor contact 140 may be formed between two of the bit lines 120. In some embodiments, the capacitor contact 140 may be formed between the first isolation spacer (i.e., the dielectric layers 132-1, 138-1 and 136-1) and the second isolation spacer (i.e., the dielectric layers 132-2, 138-2 and 136-2).

The method 200 continues with operation 218, wherein air gaps may be formed in the first isolation spacer and the second isolation spacer, respectively. For example, as shown in FIG. 2I, the air gaps 134-1, 134-2 may be formed in the first isolation spacer and the second isolation spacer, respectively. As a result, a first isolation spacer 130-1 comprising the air gap 134-1 and a second isolation spacer 130-2 comprising the air gap 134-2 may be formed. In some embodiments, a silicon oxide layer (i.e., the dielectric layers 132-1/136-1 and 132-2/136-2) of the first isolation spacer and the second isolation spacer may be removed to form the air gaps 134-1 and 134-2. In some embodiments, the air gaps 134-1 and 134-2 may be separated from the bit line 120 by a silicon nitride layer.

The method 200 continues with operation 220, wherein a stacking conductive structure, a liner, and a landing pad may be formed. For example, as shown in FIG. 2J, the stacking conductive structure 142, the liner 144, and the landing pad 146 may be formed. In some embodiments, the stacking conductive structure 142 may be formed on a top surface of the capacitor contact 140.

In some embodiments, the liner 144 may be formed on a top surface of the stacking conductive structure 142. In some embodiments, the liner 144 may be formed on a sidewall of the first isolation spacer 130-1. In some embodiments, the liner may be formed on a sidewall of the second isolation spacer 130-2.

In some embodiments, the landing pad 146 may be formed on the liner 144. In some embodiments, the landing pad 146 may be formed between two of the bit lines 120. In some embodiments, the landing pad 146 may be formed between the first isolation spacer 130-1 and the second isolation spacer 130-2. In some embodiments, the landing pad 146 may cover a top surface the first isolation spacer 130-1. In some embodiments, the air gap 134-1 of the first isolation spacer 130-1 may be covered by the landing pad 146. In some embodiments, the landing pad 146 may cover a top surface of the second isolation spacer 130-2. In some embodiments, the air gap 134-2 of the second isolation spacer 130-2 may be covered by the landing pad 146.

The method 200 continues with operation 222, wherein a portion of the landing pad 146 is removed to define an opening exposing the air gap 134-2. For example, as shown in FIG. 2K, the portion of the landing pad 146 is removed. A hole H1 (or the opening) may be defined by the landing pad 146, the dielectric layer 122, and the second isolation spacer 130-2. A portion of the air gap 134-2 may be exposed. An aspect ratio of the hole H1 may be greater than 2.

The method 200 continues with operation 224, wherein an air gap protection structure may be formed. For example, as shown in FIG. 2L, the air gap protection structure 148 is formed. In some embodiments, a deposition process may be performed to form the air gap protection structure 148.

In some embodiments, the air gap protection structure 148 may include silicon nitride and other impurities, such as carbon and/or hydrogen. In some embodiments, a temperature of the deposition process may be between about 530 °C and about 570 °C, such as 530 °C, 540 °C, 550 °C, 560 °C, or 570 °C.

In some embodiments, a pressure of the deposition process may be equal to or less than 3 torr, such as 3 torr, 2.5 torr, 2 torr, 1.5 torr, or 1 torr, or less.

In some embodiments, the deposition process may use SiH₄, NH₃, TMS, N₂, or a combination thereof. In some embodiments, the deposition process is free of Helium (He).

In some embodiments, during the deposition process, a flow rate of SiH₄ may be equal to or greater than 200 sccm, such as 200 sccm, 220 sccm, 240 sccm, 260 sccm, 280 sccm, 300 sccm, 320 sccm, or more.

In some embodiments, during the deposition process, a flow rate of NH₃ may be equal to or greater than 600 sccm, such as 600 sccm, 1,500 sccm, 2,200 sccm, 2,700 sccm, 3,200 sccm, 4,000 sccm, or more.

In some embodiments, during the deposition process, a flow rate of TMS may be equal to or greater than 45 sccm, such as 45 sccm, 48 sccm, 50 sccm, 55 sccm, or more.

In some embodiments, during the deposition process, a flow rate of N₂ may be equal to or less than 10,000 sccm, such as 10,000 sccm, 7,000 sccm, 4,000 sccm, 1,000 sccm, or less.

In some embodiments, a deposition rate of the air gap protection structure 148 may be equal to or less than 15 Å/sec, such as 12 Å/sec, 10 Å/sec, 8 Å/sec, 5 Å/sec, or less.

As a result of the process described above, during subsequent processes, the lower portion 148-1 of the air gap protection structure 148 may have a thickness sufficient to facilitate protection the air gap 134-2.

The method 200 is merely an example, and is not intended to limit the present disclosure beyond what is explicitly recited in the claims. Additional operations may be provided before, during, or after each operation of the method 200, and some operations described may be replaced, eliminated, or reordered for additional embodiments of the method. In some embodiments, the method 200 may include further operations not depicted in FIG. 3A or FIG. 3B. In some embodiments, the method 200 may include one or more operations depicted in FIG. 3A or FIG. 3B.

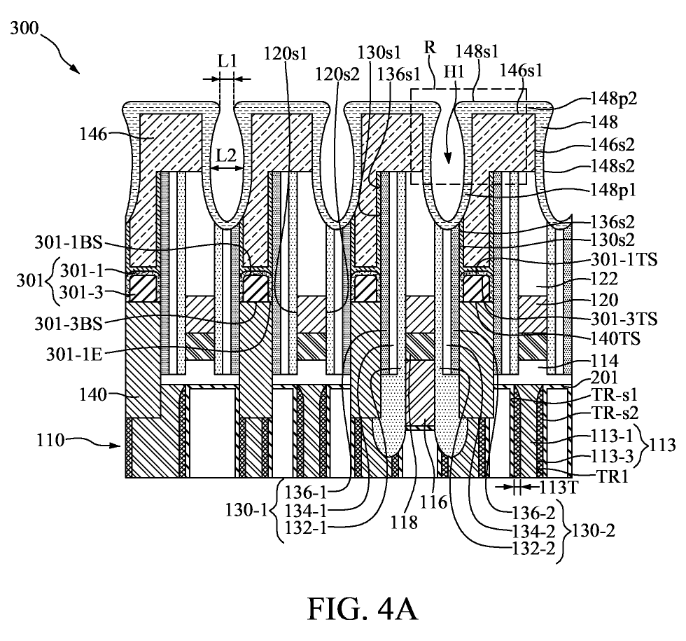

FIG. 4A is a cross-sectional view of a semiconductor device 300 in accordance with various embodiments of the present disclosure. The semiconductor device 300 may have a structure similar to that illustrated in FIG. 1A. Elements in FIG. 4A that are same as or similar to those in FIG. 1A are labeled with similar reference numbers and repeated descriptions are omitted.

Referring to FIG. 4A, the semiconductor device 300 may include a plurality of isolation structures 113 disposed in the substrate 110 and a conductive layer 301 disposed on the capacitor contact 140.

The isolation structure 113 may include an isolation layer 113-1 disposed in a trench TR1 in the substrate 110, and a plurality of liners 113-3 disposed on side surfaces TR-s1, TR-s2 of the trench TR1.

In some embodiments, the isolation layer 113-1 may include, for example, silicon oxide (SiO₂), silicon nitride (Si₃N₄), silicon oxynitride (N₂OSi₂), silicon nitride oxide (N₂OSi₂), or another suitable material.

In some embodiments, thicknesses 113T of the liners 113-3 may be between about 1.0 μm and about 10 μm. Alternatively, in some embodiments, the thicknesses of the liners 113-3 may be between about 10 nm and about 100 nm. The liners 113-3 may be formed of, for example, titanium, titanium nitride, titanium-tungsten alloy, tantalum, tantalum nitride, or a combination thereof. In some embodiments, the liners 113-3 may have a resistivity less than a resistivity of the substrate 110. The liners 113-3 may decrease an equivalent series resistance of the semiconductor device 300 and improve a performance of the semiconductor device 300. In addition, a presence of the plurality of liners 113-3 may cause a space between the active areas (or a width of the isolation layer 113-1) to be thinner. As a result, a capacitance of the semiconductor device 300 may be increased. A performance of the semiconductor device 300 is thus improved.

The conductive layer 301 may include a first portion 301-1 and a second portion 301-3. The second portion 301-3 may be disposed on the capacitor contact 140 and may have a semicircular cross-sectional profile or a semi-oval cross-sectional profile. The first portion 301-1 may be disposed covering a top surface 301-3TS of the second portion 301-3 and may have a circular arc cross-sectional profile. A top surface 301-1TS and a bottom surface 301-1BS of the first portion 301-1 may be convex. In some embodiments, two ends 301-1E of the first portion 301-1, a bottom surface 301-3BS of the second portion 301-3, and a top surface 140TS of the capacitor contact 140 may be substantially coplanar. The first portion 301-1 may have an approximately uniform thickness.

The first portion 301-1 of the conductive layer 301 may be formed of, for example, metal silicide. In some embodiments, the first portion 301-1 of the conductive layer 301 may include impurities such as phosphorus, arsenic, antimony, or boron. The second portion 301-3 of the conductive layer 301 may be formed of, for example, polycrystalline silicon, polycrystalline germanium, polycrystalline silicon-germanium, or the like. In some embodiments, the second portion 301-3 of the conductive layer 301 may include impurities such as phosphorus, arsenic, antimony, or boron.

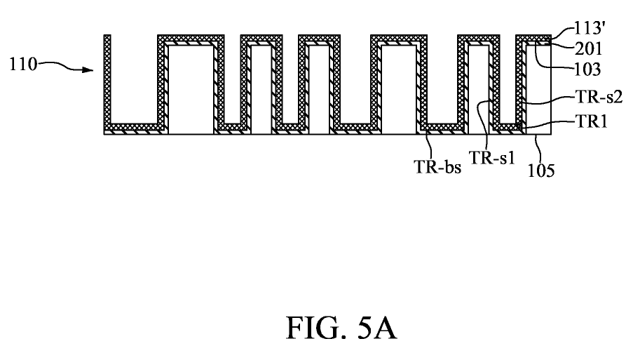

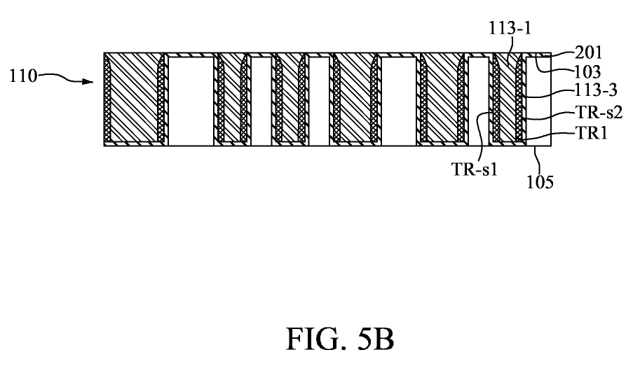

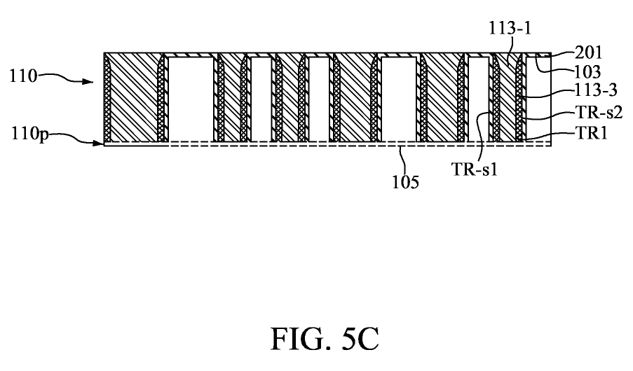

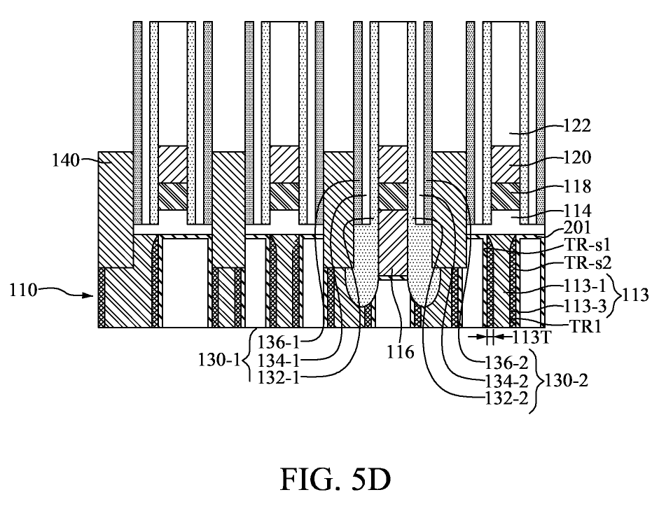

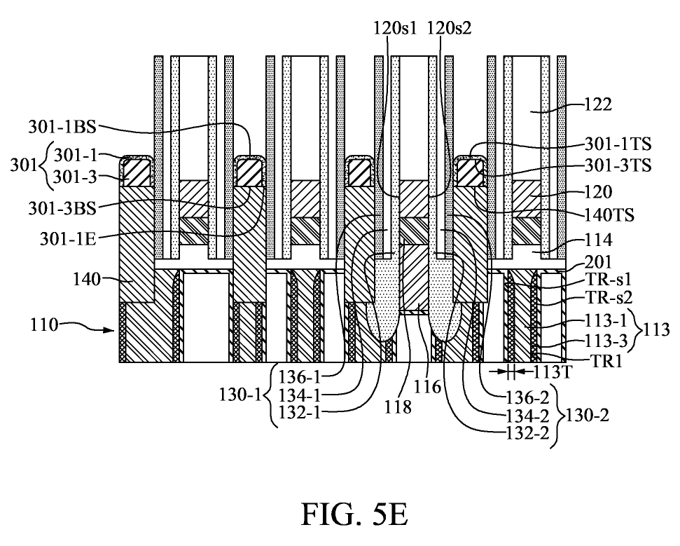

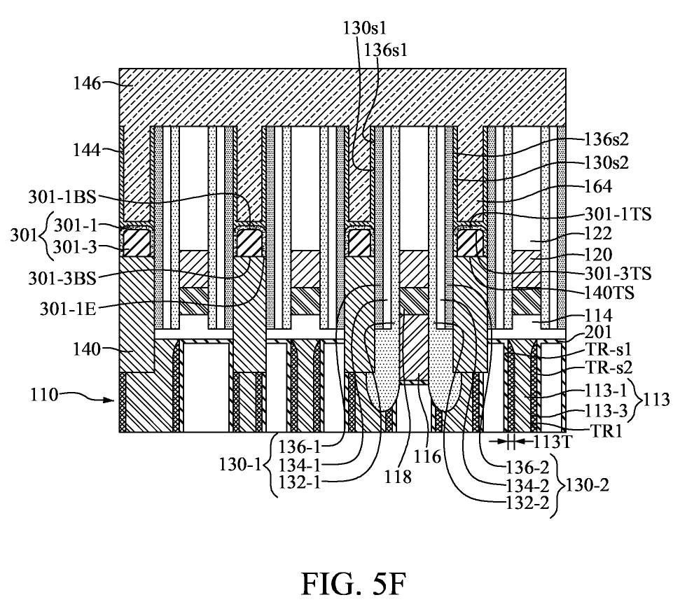

FIGS. 5A to 5C illustrate stages of manufacturing the semiconductor device 300 in accordance with operation 202 of the method 200.

Referring to FIG. 5A, a substrate 110 having a first surface 103 and a second surface 105 opposite to the first surface 103 may be provided. The substrate 110 may include a plurality of trenches TR1 disposed therein. A doped region 201 may be formed in the substrate 110. An implantation process may be performed from above the first surface 103 of the substrate 110 to form the doped region 201 in the substrate 110. The doped region 201 may be disposed in the first surface 103 of the substrate 110, and on side surfaces TR-s1, TR-s2 and a bottom surface TR-bs of the trench TR1. A resistivity of the doped region 201 may be less than or equal to a resistivity of the substrate 110. In some embodiments, the doped region 201 may be doped with a dopant such as phosphorus, arsenic, or antimony.

Next, a liner layer 113’ may be deposited on the first surface 103 of the substrate 110, the side surfaces TR-s1, TR-s2 of the trench TR1, and the bottom surface TR-bs of the trench TR1. The liner layer 113’ may be formed of, for example, titanium, titanium nitride, titanium-tungsten alloy, tantalum, tantalum nitride, or a combination thereof.

Referring to FIG. 5B, an etch process, such as an anisotropic dry etch process, may be performed to form a plurality of liners 113-3 attached to the side surfaces TR-s1, TR-s2 of the trench TR1. The plurality of liners 113-3 may be electrically connected to the doped region 201.

Next, an isolation layer 113-1 may be deposited to fill the trenches TR1. In some embodiments, the isolation layer 113-1 may include, for example, silicon oxide (SiO₂), silicon nitride (Si₃N₄), silicon oxynitride (N₂OSi₂), silicon nitride oxide (N₂OSi₂), or another suitable material. In some embodiments, a planarization process may be performed after the deposition processes to remove excess material and provide a substantially flat surface for subsequent processing steps.

Referring to FIG. 5C, part of the substrate 110 may be removed from the second surface 105 until the plurality of liners 113-3 and the isolation layer 113-1 are exposed. A removal process, such as chemical mechanical polishing, may be performed on the second surface 105 of the substrate 110 to expose the plurality of liners 113-3 and the isolation layer 113-1.

FIGS. 5D to 5F illustrate stages of manufacturing the semiconductor device 300 in accordance with operation 220 of the method 200.

Referring to FIG. 5D, an intermediate structure may be provided. The intermediate structure may have a structure similar to that of the intermediate structure shown in FIG. 2I, except that the intermediate structure in FIG. 5D may comprise a substrate 110 as described in FIG. 5C.

Referring to FIG. 5E, a plurality of second portions 301-3 may be formed on the capacitor contacts 140, respectively. The second portion 301-3 may have a semicircular cross-sectional profile or a semi-oval cross-sectional profile. Next, a plurality of first portions 301-1 may respectively be disposed covering top surfaces 301-3TS of the second portions 301-3 and may have a circular arc cross-sectional profile. In some embodiments, a top surface 301-1TS and a bottom surface 301-1BS of the first portion 301-1 may be convex. In some embodiments, two ends 301-1E of the first portion 301-1, a bottom surface 301-3BS of the second portion 301-3, and a top surface 140TS of the capacitor contact 140 may be substantially coplanar. The first portion 301-1 may have an approximately uniform thickness.

The first portion 301-1 of the conductive layer 301 may be formed of, for example, metal silicide. In some embodiments, the first portion 301-1 of the conductive layer 301 may include impurities such as phosphorus, arsenic, antimony, or boron. The second portion 301-3 of the conductive layer 301 may be formed of, for example, polycrystalline silicon, polycrystalline germanium, polycrystalline silicon-germanium, or the like. In some embodiments, the second portion 301-3 of the conductive layer 301 may include impurities such as phosphorus, arsenic, antimony, or boron. The first portion 301-1 and the second portion 301-3 together form the conductive layer 301.

Referring to FIG. 5F, a liner 144 and a landing pad 146 may be formed. The formation of the liner 144 and the landing pad 146 is same as the formation of those illustrated in FIG. 2J, and details thereof are not repeated.

One aspect of the present disclosure provides a semiconductor device. The semiconductor device comprises a substrate, a plurality of isolation structures disposed in the substrate, a bit line disposed on the substrate, an isolation spacer disposed on a sidewall of the bit line and comprising an air gap, a landing pad disposed over the bit line, and an air gap protection structure covering the landing pad and the air gap. The isolation structure comprises an isolation layer disposed in a trench in the substrate and a plurality of liners disposed on side surfaces of the trench.

Another aspect of the present disclosure provides a semiconductor device. The semiconductor device comprises a substrate, a bit line disposed on the substrate, an isolation spacer disposed on a sidewall of the bit line and comprising an air gap, a conductive layer disposed over the substrate and next to the isolation spacer, a landing pad disposed over the bit line, and an air gap protection structure covering the landing pad and the air gap. The conductive layer comprises a second portion and a first portion covering the second portion. The second portion comprises a semicircular cross-sectional profile or a semi-oval cross-sectional profile. The air gap protection structure has an upper portion above a top surface of the landing pad and a lower portion below the upper portion, and a ratio of a thickness of the lower portion to a thickness of the upper portion is greater than 0.6 and less than 0.8.

Another aspect of the present disclosure provides a method of manufacturing a semiconductor device. The method comprises providing a substrate having a first surface and a second surface opposite to the first surface, forming a trench in the first surface of the substrate, forming a plurality of liners disposed on side surfaces of the trench, forming an isolation layer filling the trench, and removing part of the substrate from the second surface to expose the isolation layer and the plurality of liners.

The embodiments of the present disclosure illustrate a semiconductor device including an air gap protection structure with an uneven thickness. The air gap protection structure includes a lower portion and an upper portion. A ratio of a thickness of the lower portion to a thickness of the upper portion is greater than 0.6 and less than 0.8, so as to protect the air gap during subsequent processes. For example, the air gap of the present disclosure may be free of metal atoms or other contaminations due to the protection of the air gap protection structure. As a result, performance of the semiconductor device is improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein, may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate;
a plurality of isolation structures disposed in the substrate, wherein the isolation structure comprises an isolation layer disposed in a trench in the substrate, and a plurality of liners disposed on side surfaces of the trench;
a bit line disposed on the substrate;
an isolation spacer disposed on a sidewall of the bit line, wherein the isolation spacer comprises an air gap;
a landing pad disposed over the bit line; and
an air gap protection structure covering the landing pad and the air gap.

2. The semiconductor device of claim 1, wherein the isolation layer of the isolation structure comprises silicon oxide (SiO₂), silicon nitride (Si₃N₄), silicon oxynitride (N₂OSi₂), silicon nitride oxide (N₂OSi₂) or a combination thereof, and the liner of the isolation structure is formed of titanium, titanium nitride, titanium-tungsten alloy, tantalum, tantalum nitride, or a combination thereof.

3. The semiconductor device of claim 2, wherein a thicknesses of the liner is between about 10 nm and about 100 nm.

4. The semiconductor device of claim 3, wherein a resistivity of the liner is less than a resistivity of the substrate.

5. The semiconductor device of claim 1, wherein the air gap protection structure comprises an upper portion above a top surface of the landing pad and a lower portion below the upper portion, and a ratio of a thickness of the lower portion to a thickness of the upper portion is greater than 0.6 and less than 0.8.

6. The semiconductor device of claim 1, wherein the air gap protection structure comprises silicon nitride.

7. The semiconductor device of claim 1, wherein the air gap protection structure comprises carbon.

8. The semiconductor device of claim 7, wherein the air gap protection structure consists of carbon with an atomic ratio equal to or greater than 4.8%.

9. The semiconductor device of claim 1, wherein the air gap protection structure comprises hydrogen.

10. The semiconductor device of claim 5, wherein a hole is defined by the landing pad and is located over the air gap, wherein the lower portion of the air gap protection structure is disposed within the hole.

11. The semiconductor device of claim 10, wherein the hole defined by the air gap protection structure comprises a smaller aperture near the upper portion of the air gap protection structure and a larger aperture near the lower portion of the air gap protection structure.

12. The semiconductor device of claim 11, wherein an aspect ratio of the hole is greater than 2.

13. The semiconductor device of claim 1, further comprising
a capacitor contact disposed in the substrate and separated from the bit line by the isolation spacer; and
a conductive layer disposed on the capacitor contact and next to the isolation spacer, wherein the conductive layer comprises a second portion and a first portion covering the second portion, and wherein the second portion comprises a semicircular cross-sectional profile or a semi-oval cross-sectional profile.

14. A semiconductor device, comprising:
a substrate;
a bit line disposed on the substrate;
an isolation spacer disposed on a sidewall of the bit line, wherein the isolation spacer comprises an air gap;
a conductive layer disposed over the substrate and next to the isolation spacer, wherein the conductive layer comprises a second portion and a first portion covering the second portion, and wherein the second portion comprises a semicircular cross-sectional profile or a semi-oval cross-sectional profile;
a landing pad disposed over the bit line; and
an air gap protection structure covering the landing pad and the air gap,
wherein the air gap protection structure comprises an upper portion above a top surface of the landing pad and a lower portion below the upper portion, and a ratio of a thickness of the lower portion to a thickness of the upper portion is greater than 0.6 and less than 0.8.

15. The semiconductor device of claim 14, wherein the isolation layer of the isolation structure comprises silicon oxide (SiO₂), silicon nitride (Si₃N₄), silicon oxynitride (N₂OSi₂), silicon nitride oxide (N₂OSi₂), or a combination thereof, and the liner of the isolation structure is formed of titanium, titanium nitride, titanium-tungsten alloy, tantalum, tantalum nitride, or a combination thereof.

16. The semiconductor device of claim 15, wherein a thicknesses of the liner is between about 10 nm and about 100 nm.

17. The semiconductor device of claim 16, wherein a resistivity of the liner is less than a resistivity of the substrate.

18. The semiconductor device of claim 14, wherein the first portion of the conductive layer covers a top surface of the second portion and comprises a circular arc cross-sectional profile.

19. The semiconductor device of claim 18, wherein a top surface and a bottom surface of the first portion are convex.

20. The semiconductor device of claim 19, wherein the first portion of the conductive layer is formed of metal silicide.
